(19) United States
(12) Patent Application Publication
(10) Pub. No.: US 2025/0336856 A1
(43) Pub. Date: Oct. 30, 2025

(54) PACKAGES WITH REDUCED BOND WAVE PROPAGATION AND THE METHODS OF FORMING THE SAME

(71) Applicant: Taiwan Semiconductor Manufacturing Co., Ltd., Hsinchu (TW)

(72) Inventors: Kuo-Chiang Ting, Hsinchu (TW); Sung-Feng Yeh, Taipei City (TW); Hao-Cheng Lin, Hsinchu (TW); Cheng-Chia Wang, Taichung City (TW); Hao-Wen Ko, Zhubei City (TW); Ling Fang, Hsinchu (TW); Chuan-An Cheng, Zhubei City (TW)

(21) Appl. No.: 19/260,986

(22) Filed: Jul. 7, 2025

Related U.S. Application Data
(63) Continuation of application No. 18/751,646, filed on Jun. 24, 2024.
(60) Provisional application No. 63/633,103, filed on Apr. 12, 2024.

(51) Int. Cl. H01L 23/00; H01L 23/367; H01L 23/498; H01L 25/065

(52) U.S. Cl. CPC H01L 24/05; H01L 23/3672; H01L 23/49816; H01L 23/49822; H01L 24/13; H01L 25/0655; H01L 2224/05009; H01L 2224/05025; H01L 2224/13009; H01L 2224/13025; H01L 2924/01029; H01L 2924/1431; H01L 2924/1434; H01L 2924/15311

(57) ABSTRACT

A method includes forming a composite carrier comprising forming a first dielectric layer on a carrier, and forming a plurality of metal pads in the first dielectric layer. The formation of the plurality of metal pads includes performing a planarization process to level first surfaces of the plurality of metal pads and the first dielectric layer. A reconstructed wafer is formed to include a plurality of device dies, and a second dielectric layer on the plurality of device dies. The composite carrier is bonded to the reconstructed wafer, and the plurality of metal pads physically contact the second dielectric layer.

### PRIORITY CLAIM AND CROSS-REFERENCE

This application is a continuation of U.S. patent application Ser. No. 18/751,646, filed on Jun. 24, 2024, which application claims the benefit of the following provisionally filed U.S. Patent application: Application No. 63/633,103, filed on Apr. 12, 2024, and entitled “A SOIC-X CHIPLET STACKING ARCHTECTURE,” which applications are hereby incorporated herein by reference.

### BACKGROUND

Integrated circuit packages may have a plurality of package components such as device dies and package substrates bonded together to increase the functionality and integration level. The bonding process may include wafer-on-wafer bonding, die-on-wafer bonding, die-to-die bonding, or the like. The bonding process may include a pre-bonding process, and an annealing process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-11A, 11B and 12 illustrate the cross-sectional views of intermediate stages in the formation of a package in accordance with some embodiments.

FIG. 13-18 illustrate some example layouts of dummy bond pads in accordance with some embodiments.

FIG. 19 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided. In accordance with some embodiments of the present disclosure, the formation of the package includes using a carrier, which includes dummy bond pads therein. With the formation of the dummy bond pads, the propagation speed of bond wave during pro-bonding is reduced. The issues such as the formation of tiny bulges are solved. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

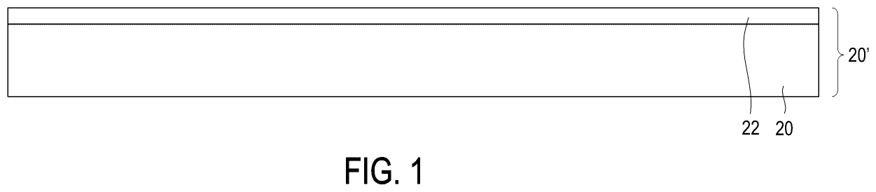

FIGS. 1 through 12 illustrate the cross-sectional views of intermediate stages in the formation of a package in accordance with some embodiments of the present disclosure. The corresponding processes are also reflected schematically in the process flow shown in FIG. 18.

Referring to FIG. 1, carrier 20 (which may be a wafer) is provided. In accordance with some embodiments, the entire carrier 20 is formed of a homogeneous material, with no other materials and structures other than the homogeneous material therein. The material of carrier 20 may have good thermal conductivity. The carrier 20 may be formed of a semiconductor material, a dielectric material, a conductive material (such as a metal), or the like. For example, carrier 20 may be a silicon wafer, which comprises elemental silicon therein. In accordance with some embodiments in which the homogeneous material comprises silicon, carrier 20 may be free from metal features and dielectric features therein.

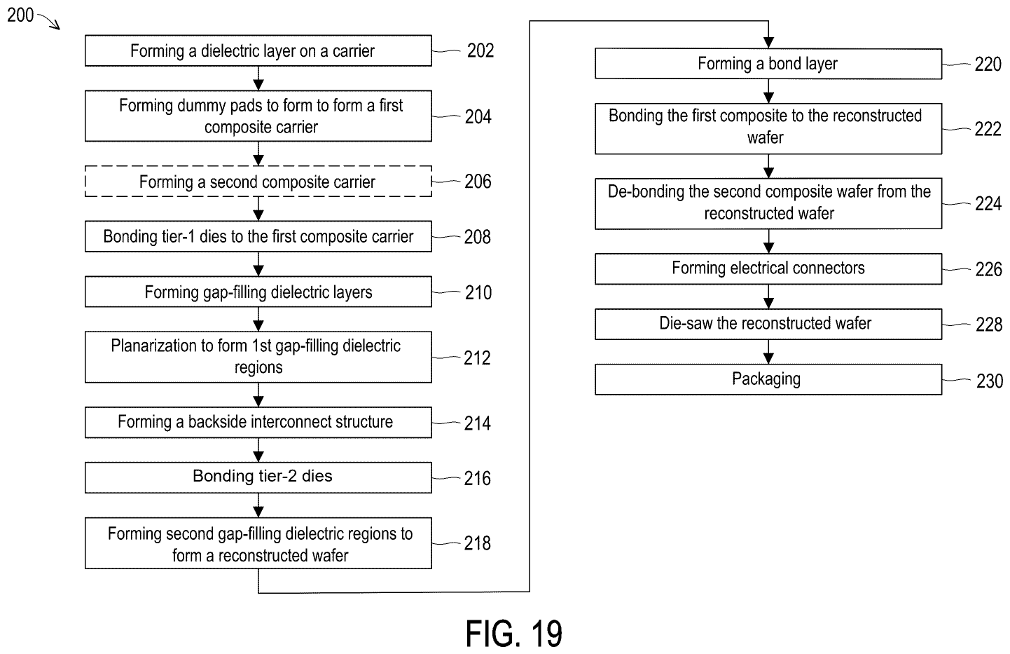

A bond layer 22 may be formed on carrier 20, with the bond layer 22 being formed of a silicon-containing dielectric material in accordance with some embodiments. The respective process is illustrated as process 202 in the process flow 200 as shown in FIG. 19. Bond layer 22 may be formed of or comprise a silicon-containing dielectric material, which may be selected from SiO, SiC, SIN, SION, SiOC, SiCN, SiOCN, or the like, or combinations thereof. Bond layer 22 may be formed of a homogeneous material, or may be a multi-layer stack including a plurality of sub layers, each formed of a material selected from SiO, SiC, SiN, SiON, SiOC, SiCN, SiOCN, or the like. The neighboring sub layers, when formed, are formed of different materials. In accordance with some embodiments, a planarization process may be performed to level the top surface of bond layer 22.

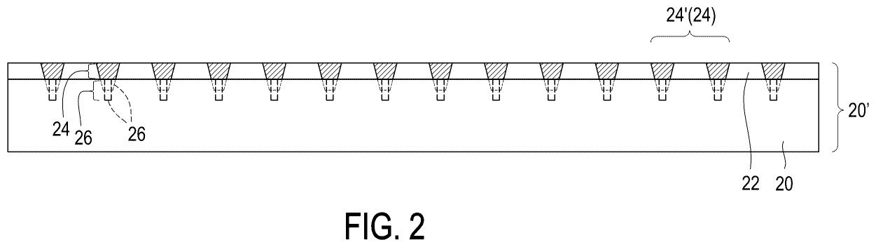

Referring to FIG. 2, a damascene process may be performed to form dummy bond pads 24 (also referred to as dummy metal pads) in bond layer 22. The respective process is illustrated as process 204 in the process flow 200 as shown in FIG. 19. Throughout the description, the structure shown in FIG. 2 is referred to as composite carrier 20′.

In accordance with some embodiments, the formation of dummy bond pads 24 may include etching bond layer 22 to form openings, and filling the openings with a material different from the material of bond layer 22. The filling material may be thermally conductive, for example, with a thermal conductivity higher than that of bond layer 22. For example, the filling material may include metal, metal alloy, polysilicon, crystalline silicon, dielectric, or the like. In accordance with some embodiments, the filling material may include a diffusion barrier (which may also be adhesion layers), and a metallic material such as copper or a copper alloy. The diffusion barrier may comprise or formed of titanium, titanium nitride, tantalum, tantalum nitride, or the like. A planarization process such as a Chemical Mechanical Polish (CMP) process or a mechanical polish process is then performed to re-expose bond layer 22.

In accordance with some embodiments, dummy bond pads 24 penetrate through bond layer 22, which may be a single layer formed of a homogeneous dielectric material, or may be a multi-layer stack including a plurality of sub layers formed of different dielectric materials. The dummy bond pads 24 may have bottoms contacting a top surface of carrier 20. In accordance with alternative embodiments when bond layer 22 includes a plurality of sub layers, dummy bond pads 24 may be overlying one or more lower sub layer and inside one or more upper sub layers. Accordingly, the dummy bond pads 24 may be physically separated from the carrier 20 by the lower sub layer(s) in accordance with these embodiments.

In accordance with some embodiments, dummy bond pads 24 extend into carrier 20, for example, for a depth small than, equal to, or greater than about 1 μm. The dashed line schematically illustrates the shape of dummy bond pads 24 when dummy bond pads 24 extend into carrier 20.

In accordance with some embodiments, dummy bond pads 24 are formed through a single damascene process. In accordance with some embodiments, a dual damascene process is performed, so that dummy bond pads 24 and vias 26 are formed, and collectively form dual damascene structures. The dummy bond pads 24 and vias 26 are also collectively referred to as dummy features hereinafter. In accordance with some embodiments, the formation of dummy bond pads 24 and vias 26 includes performing a first etching process to etch dielectric layer 22 and to form trenches, through which carrier 20 is exposed. The formation process further includes performing a second etching process to etch carrier 20 and to form via openings. The first etching process and the second etching process may be performed using separate etching masks such as different photoresists.

After the etching processes, filling materials are deposited, which may include depositing the adhesion layer (which may be a conformal layer), depositing copper, and then performing a planarization process. Vias 26 thus have sidewalls and bottoms physically contacting carrier 20, and thus vias 26 and dummy bond pads 24 may collectively act as heat dissipation paths. Vias 26 are also shown as being dashed to indicate that vias 26 may be, or may not be, formed. It is appreciated that vias 26, unlike vias formed in interconnect structures, are not for conducting electrical signals and voltages. Rather, the vias are for thermal dissipation purpose, and are also formed along with dummy bond pads 24 for reducing manufacturing cost.

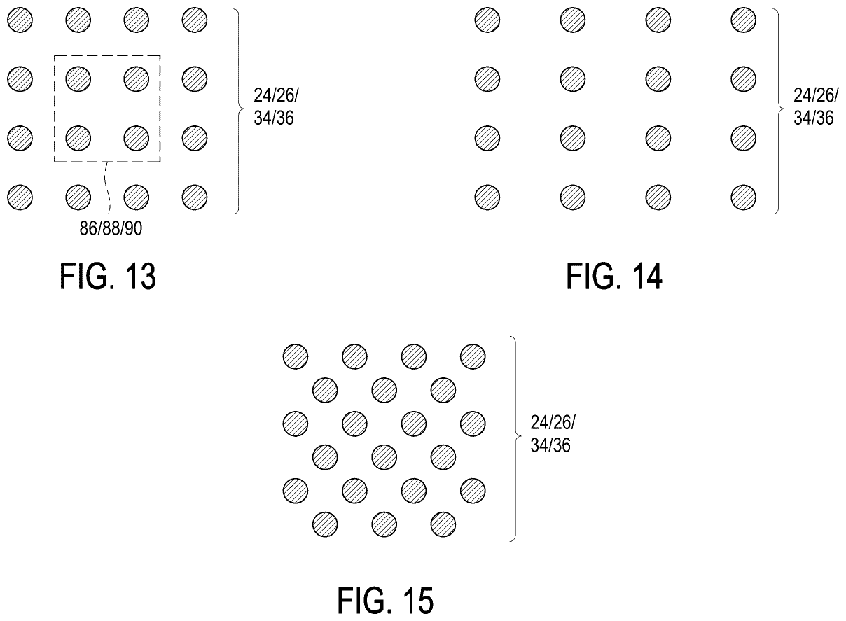

In accordance with some embodiments, dummy bond pads 24 are dummy features, which are in contact with the other package component that carrier 20 is to be attached to in subsequent processes. The dummy pads 24 may be arranged in any repeating pattern. For example, FIG. 13 through 18 illustrate the top views of some example dummy bond pads 24 (or dummy vias 26) in accordance with some embodiments. FIGS. 13, 14, 16, and 17 illustrate that dummy bond pads 24 are arranged as arrays in accordance with some embodiments. FIGS. 15 and 18 illustrate that dummy bond pads 24 are arranged as a hexagonal pattern in accordance with some embodiments.

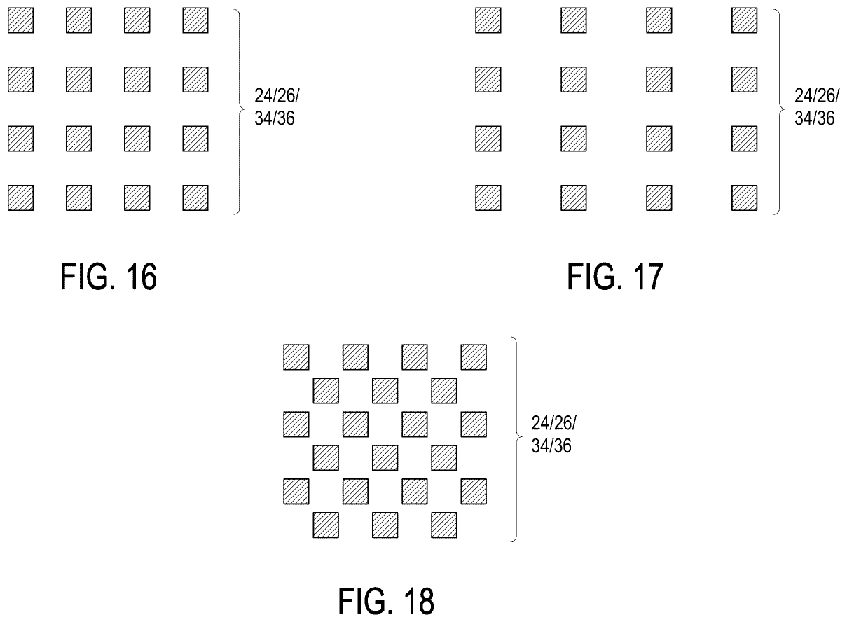

The shapes of dummy bond pads 24 may have any applicable shape including, and not limited to, circles (as shown in FIGS. 13 through 15), rectangles, squares (as shown in FIGS. 16 through 18), hexagons, octagons, ovals, or the like. The pattern density (in the top view) of dummy bond pads 24 may be in the range between about 5 percent and about 15 percent. The top view density of dummy bond pads 24 may be uniform or substantially uniform throughout carrier 20.

In accordance with some embodiments, dummy bond pads 24 may include alignment marks (schematically marked as 24′ in FIG. 2), which may have the shapes and patterns different from the shapes and/or patterns of other dummy bond pads 24, so that the alignment marks 24′ may be identified and used for aligning carrier 20 with other package components. When the alignment marks 24′ are formed, the alignment marks 24′ may be formed in the same formation process as other dummy bond pads 24. Furthermore, since alignment marks 24′ are formed, there is no need to form other additional alignment marks, for example, in a lower dielectric layer of the of bond layer 22 that is underlying the top dielectric layer of bond layer 22.

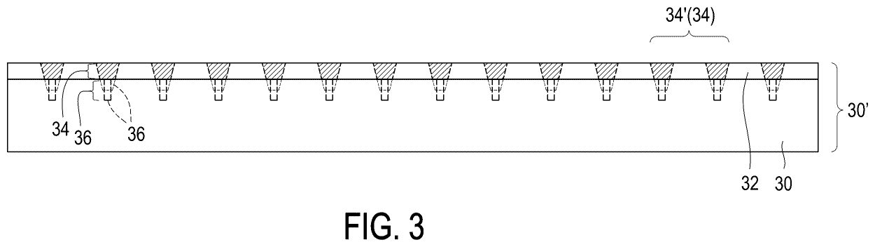

FIG. 3 illustrates the formation of a second composite carrier 30′ in accordance with some embodiments, which is formed based on carrier 30. Composite carrier 30′ may include carrier 30, dielectric layer 32, and dummy features that include dummy pads 34, and may or may not include dummy vias 36. The respective process is illustrated as process 206 in the process flow 200 as shown in FIG. 19. In accordance with some embodiments, carrier 30 is a semiconductor carrier such as a silicon carrier, and dielectric layer 32 is a bond layer. Bond layer 32 may also be formed of a silicon-containing dielectric material selected from SiO, SiC, SiN, SiON, SiOC, SiCN, SiOCN, or the like, or combinations thereof.

In accordance with some embodiments, dummy pads 34 are formed, which may include alignment mark 34′. Vias 36 may be, or may not be formed to extend into carrier 30. The details (including the structures, the materials, and the formation processes) of the features shown in composite carrier 30′ may be found from the discussion of the like features in FIG. 2, and thus the details are not repeated herein.

In accordance with alternative embodiments, no dummy pads 34 are formed in bond layer 32. The corresponding alignment marks (not shown) in may be formed in accordance with some embodiments. The alignment marks that are formed without the formation of dummy pads may be covered by a top sub layer of layer 32, and are not exposed in accordance with some embodiments. The process 206 (FIG. 19) is thus illustrated as being dashed to indicate that a carrier 30 may be used without the formation of dummy pads 34, or a composite carrier 30′ including dummy pads 34 may be used. In subsequent discussion of the example embodiments, composite carrier 30′ is used as an example, while a composite carrier 30′ without dummy pads 34 may also be used.

In accordance with alternative embodiments, carrier 30 includes a transparent substrate such as a glass substrate, and layer 32 may be formed of an adhesive such as a light-to-heat-Conversion (LTHC) material, which is configured to be decomposed under the heat of light (such as a laser beam).

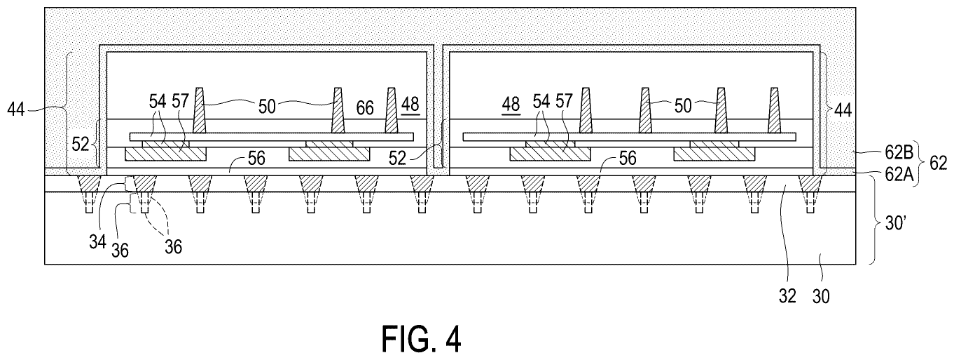

Referring to FIG. 4, device dies 44 (tier-1 dies) are bonded (attached) to composite carrier 30. The respective process is illustrated as process 208 in the process flow 200 as shown in FIG. 19. In accordance with some embodiments, each of device dies 44 may be a logic die such as an Application Specific Integrated Circuit (ASIC) die, which may be a Central Processing Unit (CPU) die, a microcontroller (MCU) die, an input-output (IO) die, a BaseBand die, or the like. Device dies 44 may also include memory dies such as Static Random-Access Memory (SRAM) dies, Dynamic Random-Access Memory (DRAM) dies, or the like.

Devices dies 44 may include semiconductor substrates 48, which may be silicon substrates. Through-Silicon Vias (TSVs) 50, sometimes referred to as through-substrate vias, through-semiconductor vias or through-vias, are formed to extend into semiconductor substrates 48. TSVs 50 are used to connect the devices and metal lines formed on the front side (the illustrated bottom side) of semiconductor substrates 48 to the features on the backside. Also, device dies 44 include interconnect structures 52 for connecting to the integrated circuit devices (active devices and passive devices, not shown) in device dies 44. Interconnect structures 52 include metal lines and vias 54 in accordance with some embodiments.

Each of device dies 44 may include a bond layer 56 (also referred to as a bond film) at the illustrated bottom surface of device die 44. In accordance with some embodiments, bond layer 56 may be formed of a silicon-containing dielectric material, which may be selected from SiO, SiC, SIN, SiON, SiOC, SiCN, SiOCN, or the like, or combinations thereof.

The bonding of device dies 44 to composite carrier 30′ may be achieved through fusion bonding, wherein bond layers 56 are bonded to bond layer 32. The bond pads 34, on the other hand, may be in physical contact with, but are not bonded to, bond layers 56. Accordingly, bond pads 34 are also referred to as dummy bond pads 34. The bonding may also be referred to as a pseudo hybrid bonding due to that one side of the bonded structure includes bond pads, but the other side does not have bond pads.

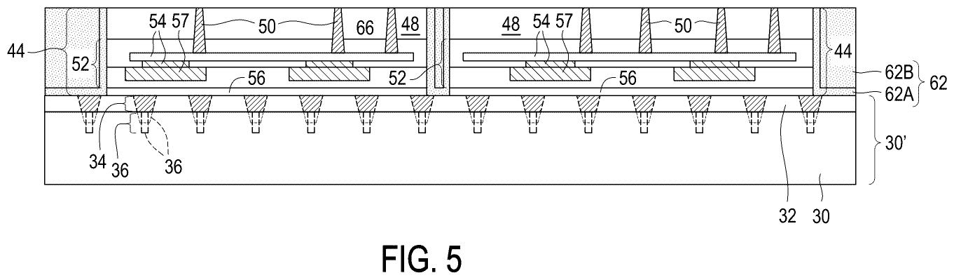

FIGS. 4 and 5 further illustrate the formation of dielectric gap-filling regions 62. The respective process is illustrated as process 210 in the process flow 200 as shown in FIG. 19. Referring to FIG. 4, in accordance with some embodiments, gap-filling dielectric layers are formed. A dielectric liner 62A is first formed, and a dielectric filling layer 62B is formed over and contacting the dielectric liner 62A. The dielectric liner 62A may be deposited using a conformal deposition method such as Atomic Layer Deposition (ALD) or Chemical Vapor Deposition (CVD). The dielectric liner 62A is formed of a dielectric material that has good adhesion to the sidewalls of device dies 44 and to the top surface of bond layer 32. In accordance with some embodiments, the dielectric liner 62A is formed of a nitrogen-containing material such as silicon nitride, SiON, SiCN, or the like. The dielectric liner 62A extends on, and physically contacts, the sidewalls and the top surfaces of device dies 44.

The dielectric filling layer 62B is deposited on the dielectric liner 62A. The dielectric filling layer 62B is formed of a material different from the material of the dielectric liner 62A. In accordance with some embodiments, the dielectric filling layer 62B is formed of silicon oxide, while other dielectric materials such as silicon carbide, silicon oxynitride, silicon oxy-carbo-nitride, or the like may also be used.

Next, as shown in FIG. 5, a planarization process such as a CMP process or a mechanical grinding process is performed to remove excess portions of the dielectric filling layer 62B and the dielectric liner 62A, so that device dies 44 are exposed. The respective process is illustrated as process 212 in the process flow 200 as shown in FIG. 19. Also, through-vias 50 are exposed by the planarization process. The remaining portions of the dielectric liner 62A and the dielectric filling layer 62B are collectively referred to as (gap-filling) dielectric isolation regions 62 or dielectric gap-filling regions 62.

In accordance with alternative embodiments, the dielectric isolation regions 62 may include a molding compound, a molding underfill, an epoxy, a resin, or the like. The formation process may include dispensing the material of dielectric isolation regions 62 in a flowable form, curing the material, and then performing a planarization process such as a CMP process or a mechanical grinding process, until TSVs 50 are exposed.

In accordance with alternative embodiments, instead of performing die-on-wafer bonding to bond device dies 44 to composite carrier 30′, a wafer-on-wafer bonding process may be performed. In accordance with these embodiments, device dies 44 may be parts of an un-sawed device wafer. Alternatively, device dies may be discrete dies that are encapsulated by dielectric gap-filling regions 46 to form a reconstructed wafer, which reconstructed wafer is then bonded to the composite carrier 30′ through wafer-on-wafer bonding.

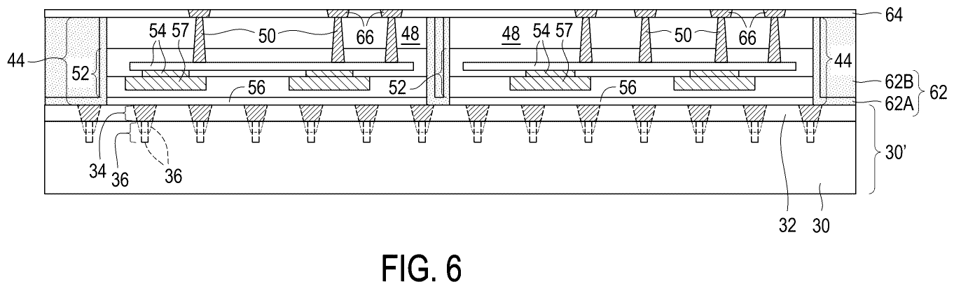

Referring to FIG. 6, a (backside) interconnect structure is formed on the backside of device dies 44. The respective process is illustrated as process 214 in the process flow 200 as shown in FIG. 19. The backside structure includes bond layer 64, and bond pads 66 in bond layer 64. Bond layer 64 may include a silicon-containing dielectric material as aforementioned. The bond pads 66 may include copper, and may be formed using a single damascene process. In accordance with some embodiments, the backside interconnect structure may include a plurality of dielectric layers, and redistribution lines (RDLs, not shown) and bond pads 66 in the dielectric layers. Bond pads 66 and the RDLs (when formed) are electrically connected to the integrated circuits in the device dies 44.

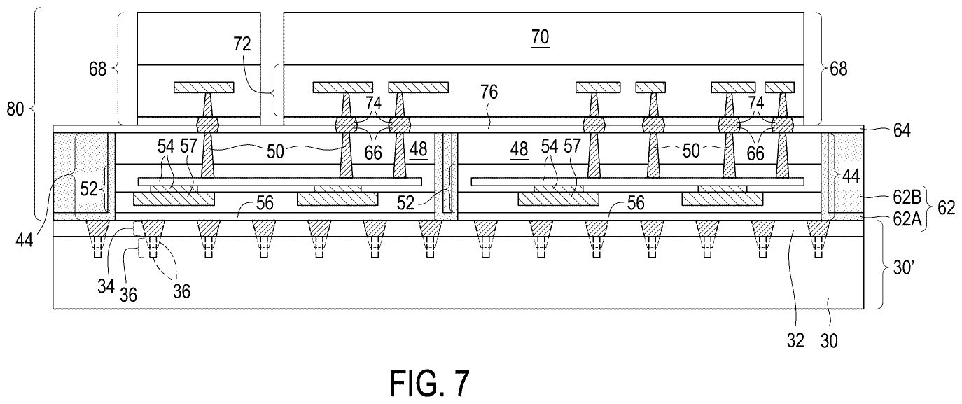

Referring to FIG. 7, device dies 68 (tier-2 dies) are bonded to the bond pads 66 of the backside interconnect structure. The respective process is illustrated as process 216 in the process flow 200 as shown in FIG. 19. Device dies 68 may include semiconductor substrates 70, interconnect structures 72, bond pads 74, and bond layers 76. In accordance with some embodiments, the bond pads 74 are bonded to the bond pads 66 through metal-to-metal direct bonding, and bond layers 76 are bonded to the bond layer 64 through fusion bonding.

In accordance with some embodiments, each of device dies 68 may be a logic die such as an ASIC die, which may be a CPU die, a MCU die, an IO die, or the like. Device dies 68 may also include memory dies such as SRAM dies, DRAM dies, or the like.

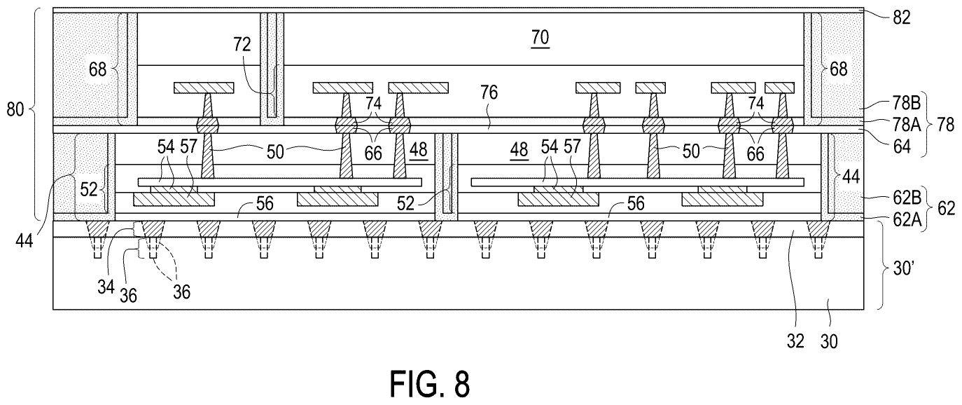

Referring to FIG. 8, dielectric gap-filling regions 78 are formed, which may include a dielectric liner 78A and a dielectric filling layer 78B. The respective process is illustrated as process 218 in the process flow 200 as shown in FIG. 19. In accordance with some embodiments, the dielectric liner 78A is formed, and the dielectric filling layer 78B is deposited over and contacting the dielectric liner 78A. The dielectric liner 78A may be deposited using a conformal deposition process such as ALD or CVD. The dielectric liner 78A is formed of a dielectric material that has good adhesion to the sidewalls of device dies 68. In accordance with some embodiments, the dielectric liner 78A is formed of a nitrogen-containing material such as silicon nitride, SiON, SiCN, or the like. The dielectric liner 78A extends on, and contacts, the sidewalls and the top surfaces of device dies 68.

The dielectric filling layer 78B may be formed of a material different from the material of the dielectric liner 78A. In accordance with some embodiments, the dielectric filling layer 78B is formed of silicon oxide, while other dielectric materials such as silicon carbide, silicon oxynitride, silicon oxy-carbo-nitride, or the like may also be used.

Next, a planarization process such as a CMP process or a mechanical grinding process is performed to remove excess portions of the dielectric filling layer 78B and the dielectric liner 78A, so that device dies 68 are exposed. The remaining portions of the dielectric liner and the dielectric filling layer are collectively referred to as dielectric gap-filling regions 78.

In accordance with alternative embodiments, the dielectric gap-filling regions 78 may include a molding compound, a molding underfill, an epoxy, a resin, or the like. The formation process may include dispensing the material of dielectric gap-filling regions 78 in a flowable form, curing the material, and then performing a planarization process such as a CMP process or a mechanical grinding process. Throughout the description, the structure over composite carrier 30′ is referred to as a reconstructed wafer 80.

Next, as also shown in FIG. 8, bond layer 82 is deposited on device dies 68 and dielectric gap-filling regions 78 to further expand reconstructed wafer 80. The respective process is illustrated as process 220 in the process flow 200 as shown in FIG. 19. In accordance with some embodiments, bond layer 82 may comprise a silicon-containing dielectric material such as SiO, SiN, SiC, SiCN, SiOCN, SiOC, or the like. A planarization process may be (or may not be) performed to further make the top surface of bond layer 82 planar enough for the subsequent bonding process.

Next, the composite carrier 20′ is bonded to the reconstructed wafer 80 to form reconstructed wafer 84. The respective process is illustrated as process 222 in the process flow 200 as shown in FIG. 19. In accordance with some embodiments, the bonding of composite carrier 20′ to bond layer 82 may be achieved through fusion bonding, wherein bond layer 22 is bonded to bond layer 82. The dummy bond pads 24, on the other hand, are in physical contact with, but are not bonded to, bond layer 82. This means that if bond layers 22 and 82 lose bonding ability, composite carrier 20′ will be detached from reconstructed wafer 80. Accordingly, dummy bond pads 24 are also referred to as dummy bond pads 24. The bonding may also be referred to as a pseudo hybrid bonding due to that one side of the bonded structure includes bond pads, while the other side does not have bond pads.

In accordance with some embodiments, composite carrier 20′ includes dummy pads 24 (and may or may not include (dummy) vias 26), and composite carrier 30′ includes dummy pads 34 (and may or may not include (dummy) vias 36). For example, when another reconstructed wafer is pre-formed to include device dies 44 and dielectric gap-filling regions 46, the using of composite carrier 30′ (rather than a carrier without dummy pads) may help to reduce bond wave propagation speed and to reduce non-bond regions, as will be discussed in subsequent paragraphs.

In accordance with alternative embodiments, composite carrier 20′ includes dummy pads 24 (and may or may not include vias 26), while composite carrier 30′ does not include dummy pads and dummy vias 36. Since the bonding of device dies 44 to composite carrier 30′ may be through die-on-wafer bonding, the problem caused by fast bond wave propagation is less severe than in wafer-on-wafer bonding, and the composite carrier 30′ does not have heat-dissipation function (since it may be removed), not forming dummy pads 34 may reduce manufacturing cost. Composite carrier 20′, on the other hand, may have dummy pads 24, which help to reduce bond wave propagation speed and improve heat dissipation, as will be discussed in subsequent paragraphs.

The bonding of carrier 20 to reconstructed wafer 80 may include a pre-bonding process, followed by an annealing process. In accordance with some embodiments, during the pre-bonding process, composite carrier 20′ is put into contact with the reconstructed wafer 80, with a pressing force applied to press composite carrier 20′ and reconstructed wafer 80 against each other. The pre-bonding may be performed at room temperature (between about 20° C. and about 25° C.), and a higher temperature may also be used.

The pre-bonding may start from putting the center of composite carrier 20′ into contact with reconstructed wafer 80. The contacting propagates from the contacting point to the edges of composite carrier 20′ and reconstructed wafer 80, which propagation generates a bond wave propagating from the contacting point to the edges. With the bond wave propagating from the contacting point to the edges, the air between composite carrier 20′ and reconstructed wafer 80 is gradually squeezed out, so that no air bubble or moisture is trapped between composite carrier 20′ and reconstructed wafer 80.

During the propagation of the bond wave, since the bond wave propagation may be fast, bulges may occur at some points. This will cause some tiny non-bond regions to occur. In accordance with the embodiments of the present disclosure, since dummy bond pads 24 have different compositions and different properties than bond layers 22 and 82, the bond wave travels through the dummy bond pads 24 and bond layers 22 and 82 at different speed. Accordingly, the bond wave propagation is disrupted and discontinuous when running into the dummy bond pads 24. The bond wave propagation behavior in different directions is thus different. The bulges and the tiny non-bond regions are hence at least reduced, and possibly eliminated.

In accordance with some embodiments, to effectively disrupt the bond wave, the sizes and the pitches of the dummy bond pads 24 are selected, so that the bond wave is effectively disrupted. In accordance with some embodiments, the lengths and widths (when viewed in the top view such as shown in FIGS. 13 through 18) of the dummy bond pads 24, which may be equal to each other or different from each other, may be in the range between about 1 μm and about 20 μm. The pitches of the dummy bond pads 24, which may also be equal to each other or different from each other, may be in the range between about 1 μm and about 100 μm. The total area of the dummy bond pads 24 may be less than about 15 percent, and may be in the range between about 5 percent and about 15 percent, of the total area of the respective chip or wafer.

After the pre-bonding process, an annealing process is performed, for example, with Si—O—Si bonds being formed between bond layers 22 and 82, so that bond layers 22 and 82 are bonded to each other through fusion bonding. In accordance with some embodiments, the annealing process is performed at a temperature in the range between about 250° C. and about 300° C. The annealing duration may be in the range between about 5 minutes and about 30 minutes.

In accordance with some embodiments, some or all of dummy bond pads 24 are in contact with dielectric materials including, for example, dielectric layers 22 and 82 from sides and bottoms. The top surfaces of dummy bond pads 24, on the other hand, may be in contact with the semiconductor carrier 20 in accordance with some embodiments. In accordance with alternative embodiments, dummy bond pads 24 are fully enclosed in dielectric materials when dielectric layer 22 includes a sub layer between dummy bond pads 24 and carrier 20.

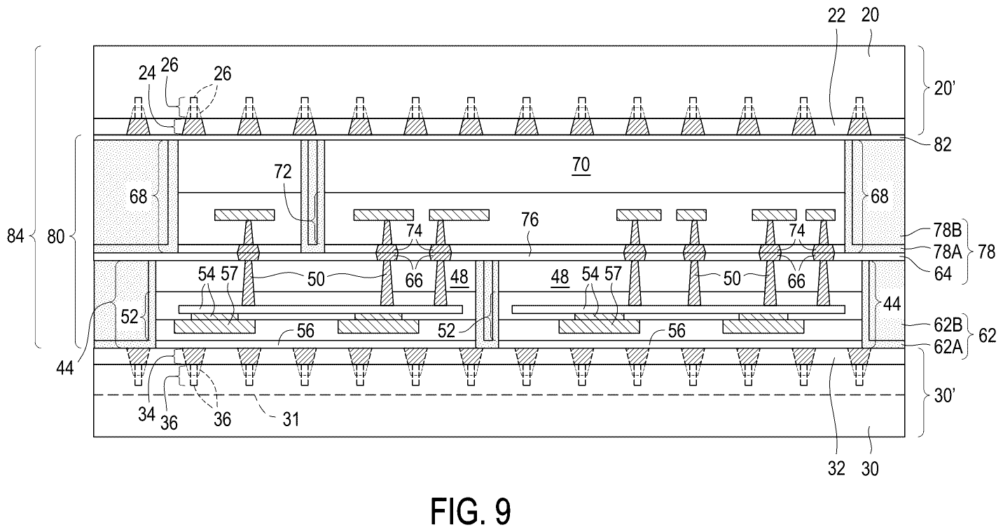

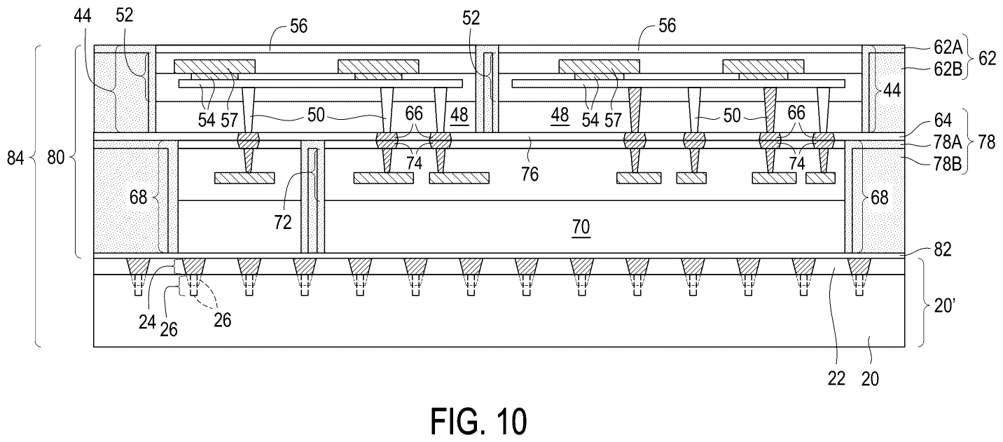

Next, reconstructed wafer 80 and composite carrier 20′ are de-bonded from composite carrier 30′. The respective process is illustrated as process 224 in the process flow 200 as shown in FIG. 19. The resulting structure is shown in FIG. 10. In accordance with some embodiments in which carrier 30 includes a silicon substrate, the de-bonding may be achieved by implanting an element such as hydrogen into an intermediate location in the carrier 30, and performing an annealing process so that the carrier 30 may break apart where the implanted element is concentrated. Accordingly, a majority of the carrier 30 is broken apart from the rest of the carrier 30, which includes a smaller portion of the carrier 30. For example, the breaking may occur at the plane shown by dashed line 31 in FIG. 9.

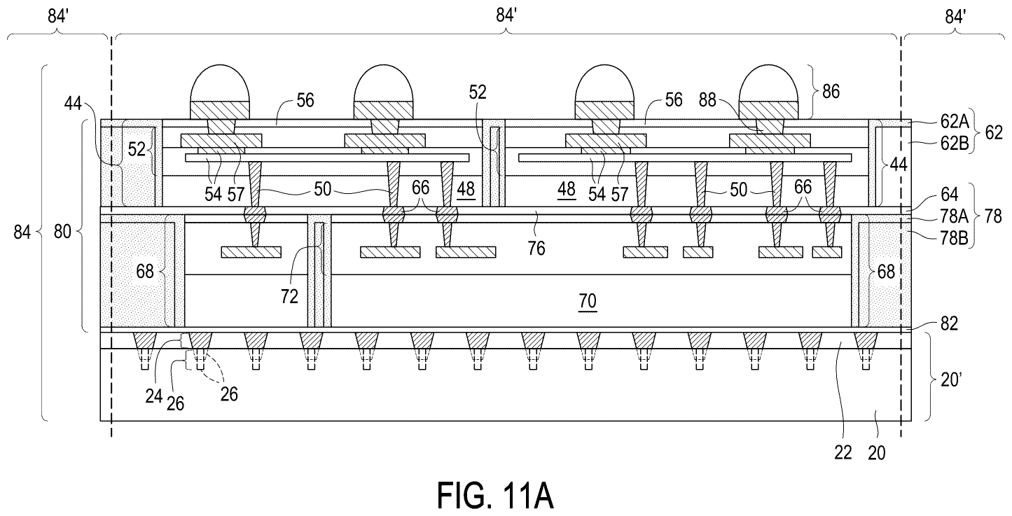

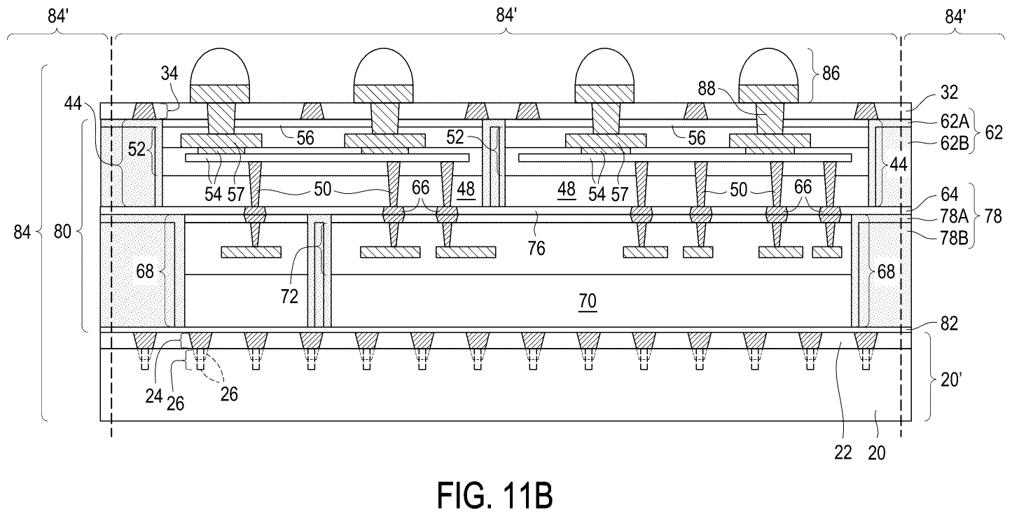

After the majority part of carrier 30 is broken apart, a planarization process such as a CMP process or a mechanical grinding process is performed to remove the remaining part of carrier 30. In accordance with some embodiments, the planarization process may be performed after bond layer 32 is removed, and the dielectric layers 56 of device dies 44 are revealed, as shown in FIG. 10. In accordance with alternative embodiments, the planarization process is stopped when bond layer 32 is still left in the reconstructed wafer 80, and may be in the final structure, for example, in the package as shown in FIG. 11B.

In accordance with alternative embodiments in which the carrier 30 comprises a glass wafer, and an LTHC layer is used to adhere carrier 30 to the reconstructed wafer 80, a laser beam may be projected on the LTHC layer, so that the LTHC layer is decomposed, and thus the carrier 30 may be detached from the reconstructed wafer 80. In accordance with some embodiments, the dielectric layers 56 of device dies 44 are revealed.

In subsequent processes, as shown in FIG. 11A, electrical connectors 86 are formed. The respective process is illustrated as process 226 in the process flow 200 as shown in FIG. 19. Vias 88 may also be formed to connect electrical connectors 86 to the interconnect structure 52. Electrical connectors 86 may comprise solder regions, metal pillars, and/or the like. In accordance with some embodiments, the formation of electrical connectors 86 may include etching dielectric layers 56 of device dies 44 (and bond layer 32, if remaining) to form via openings. Conductive features 57, which may be metal pads, are revealed through the via openings.

In accordance with some embodiments in which electrical connectors 86 and vias 88 are formed, a seed layer is deposited, which extends into the via openings. A plating mask (such as a photoresist) is then formed and patterned to form openings, which are directly over the conductive features 57. A conductive material such as copper is then plated in the openings of the plating mask. In accordance with some embodiments, a solder layer may (or may not) be plated. The plating mask is then removed, followed by the removal of the portions of the seed layer previously covered by the plating mask.

In subsequent processes, as also shown in FIG. 11A, reconstructed wafer 84 is singulated in a sawing process, so that discrete packages 84′ are formed. The respective process is illustrated as process 228 in the process flow 200 as shown in FIG. 19. The resulting packages 84′ may include dummy pads 24, which are in contact with (but are not bonded to) dielectric layer 82.

FIG. 11B illustrates the reconstructed wafer 84 and the corresponding packages 84′ in accordance with alternative embodiments. In accordance with these embodiments, in the de-bonding process of composite carrier 30′, carrier 30 is removed, while bond layer 32 and dummy pads 34 are left unremoved. Dummy vias 36 are also removed if they are formed. In accordance with these embodiments, vias 88 will also penetrate through the bond layer 32 to electrically connect to conductive features 57. In accordance with these embodiments, dummy pads 34 may be formed where electrical connectors 86 and vias are not to be formed. Accordingly, the dummy pads 34 may generally form a repeated pattern as shown in FIGS. 13 through 18, except in locations where electrical connectors 86 and vias 88 are to be formed. For example, FIG. 13 illustrates region 90, in which an electrical connector 86 and a via 88 are formed. Accordingly, the dummy pads 34 and dummy vias 36 in region 90 will not be formed, and region 90 is surrounded by dummy pads 34 and dummy vias 36.

In accordance with alternative embodiments, carrier 20 may also be de-bonded from the package components bonded thereon including device dies 44 and device dies 68. In accordance with some embodiments in which carrier 20 includes a silicon substrate, the de-bonding may be achieved by implanting an element such as hydrogen into an intermediate level in the carrier 20, and performing an annealing process so that the carrier 20 may break apart where the concentration of the implanted elements is highest. In accordance with alternative embodiments in which the carrier 20 comprises a glass wafer, and an LTHC layer is used to adhere carrier 20 to the reconstructed wafer 80, a laser beam may be projected on the LTHC layer, so that the LTHC layer is decomposed, and thus the carrier 20 may be detached from the reconstructed wafer 80.

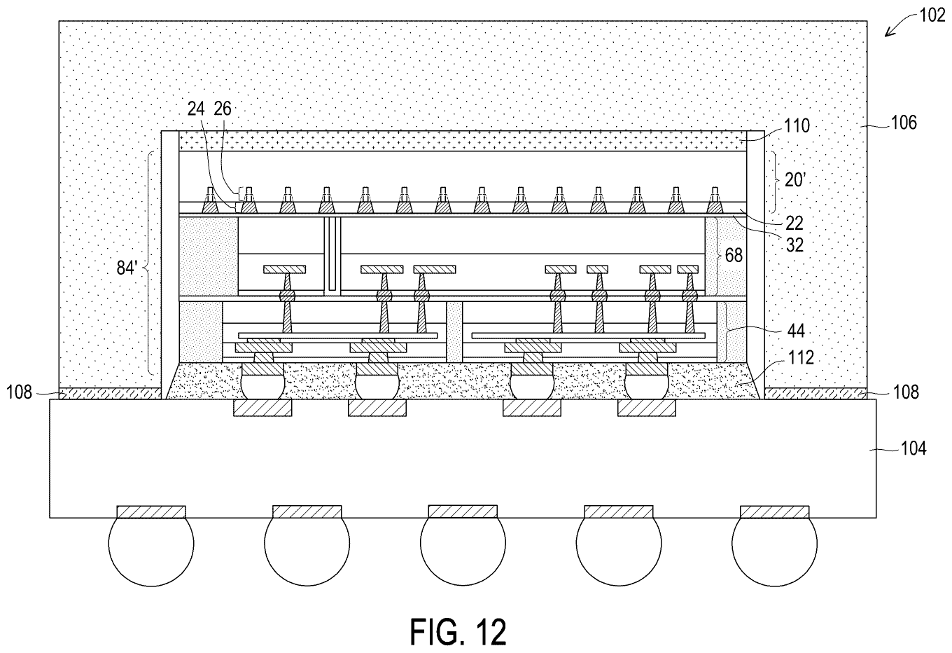

FIG. 12 illustrates the formation of a package 102 that incorporates the package 84′ in accordance with some embodiments. The respective process is illustrated as process 230 in the process flow 200 as shown in FIG. 19. Package 84′ may be bonded to package component 104, which may be or may include a package substrate, a silicon interposer, an organic interposer, another package, and/or the like. Heat sink 106, which is alternatively referred to as a heat spreader, is attached to package 84′ through Thermal Interface Material (TIM) 110, which may include an adhesive and thermally conductive particles therein. Heat sink 106 may be formed of copper, aluminum, or other metals. Heat sink 106 is also attached to package component 104 through adhesive 108. Underfill 112 may be dispensed in the gap between package 84′ and package component 104. Package 102 is thus formed.

In the structure shown in FIG. 12, the heat generated in device dies 44 and 68 may be dissipated to heat sink 106 through composite carrier 20′. Since silicon and metal have higher thermal conductivity values than some dielectric materials such as silicon oxide, silicon nitride, or the like, by forming dummy bond pads 24 that are in contact with carrier 20, the dummy bond pads act as effective thermally conductive paths for conducting the heat generated in device dies 44 and 68 into the heat sink 106. Furthermore, even if the dummy bond pads 24 do not fully penetrate through the dielectric layer 22 on the surface of the carrier 20, the heat conduction efficiency is still improved since the highly thermally conductive paths are at least in some parts of the of dielectric layer 22.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming dummy bond pads in a surface layer of a composite carrier, the bond wave propagation speed during the pre-bonding of the composite carrier to another package component is reduced. The non-bond problem that otherwise may occur is thus reduced or eliminated. In addition, by forming dummy bond pads, which are inside and may possibly penetrate through the dielectric layer(s) on a surface of the composite carrier, the heat dissipation efficiency is improved.

In accordance with some embodiments of the present disclosure, a method comprises forming a first composite carrier comprising forming a first dielectric layer on a carrier; and forming a plurality of metal pads in the first dielectric layer, wherein the forming the plurality of metal pads comprises performing a planarization process to level first surfaces of the plurality of metal pads and the first dielectric layer; forming a reconstructed wafer comprising a plurality of device dies; and a second dielectric layer on the plurality of device dies; and bonding the first composite carrier to the reconstructed wafer, wherein the plurality of metal pads physically contact the second dielectric layer.

In an embodiment, at a time of the bonding, the second dielectric layer is a blank layer free from metal features therein. In an embodiment, the forming the plurality of metal pads comprises performing a first etching process to etch the first dielectric layer and to form a first plurality of openings, until the carrier is exposed; and filling the first plurality of openings with a metallic material, wherein the planarization process is performed on the metallic material. In an embodiment, the forming the plurality of metal pads further comprises performing a second etching process to etch the carrier and to form a second plurality of openings in the carrier, wherein the metallic material is filled in the second plurality of openings.

In an embodiment, the plurality of metal pads and the second dielectric layer are free from bonds therebetween. In an embodiment, the first dielectric layer is bonded to the second dielectric layer through fusion bonding. In an embodiment, the method further comprises forming the reconstructed wafer comprising bonding the plurality of device dies over a second composite wafer; forming a plurality of dielectric gap-filling regions encapsulating the plurality of device dies; and depositing the second dielectric layer on the plurality of dielectric gap-filling regions. In an embodiment, the method further comprises de-bonding the first composite carrier from the reconstructed wafer. In an embodiment, the de-bonding the first composite carrier from the reconstructed wafer comprises breaking a first part of the carrier from a second part of the carrier; and performing a polishing process on the second part of the carrier to remove the second part from the reconstructed wafer.

In accordance with some embodiments of the present disclosure, a structure comprises a composite carrier comprising a carrier; a first dielectric layer on the carrier; and a plurality of dummy bond pads in the first dielectric layer, wherein the plurality of dummy bond pads are in contact with the carrier; a first device die over the composite carrier, wherein the first device die comprises a semiconductor substrate; a dielectric gap-filling region surrounding the first device die; and a second dielectric layer underlying and overlapped by both of the dielectric gap-filling region and the first device die, wherein the second dielectric layer physically contacts the plurality of dummy bond pads and the first dielectric layer.

In an embodiment, the second dielectric layer is further in physical contact with the dielectric gap-filling region and the first device die. In an embodiment, the structure further comprises metal vias in the carrier and joined to the plurality of dummy bond pads. In an embodiment, the first dielectric layer comprises a plurality of sub layers, and wherein the plurality of dummy bond pads penetrate through the plurality of sub layers.

In an embodiment, the structure further comprises a third dielectric layer over and contacting the first device die; and a second device die over and contacting the third dielectric layer. In an embodiment, the structure further comprises a thermal interface material over and joined to the second device die; and a heat sink over and contacting the thermal interface material. In an embodiment, first edges of the second dielectric layer are vertically aligned to second edges of the carrier.

In accordance with some embodiments of the present disclosure, a structure comprises a silicon carrier; a first dielectric layer over the silicon carrier; a dummy conductive feature in the first dielectric layer, wherein the dummy conductive feature is in physical contact with the silicon carrier; a second dielectric layer over the first dielectric layer, wherein a first top surface of the dummy conductive feature contacts a bottom surface of the second dielectric layer to form a horizontal interface; and a device die comprising a semiconductor substrate, wherein the semiconductor substrate physically contacts the second dielectric layer. In an embodiment, a bottom surface of the dummy conductive feature contacts a second top surface of the silicon carrier. In an embodiment, a bottommost end of the dummy conductive feature is higher than a bottom surface of the silicon carrier. In an embodiment, the second dielectric layer is free from conductive features penetrating through.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first composite carrier comprising:
forming a first dielectric layer on a carrier; and
forming a plurality of metal pads in the first dielectric layer, wherein the forming the plurality of metal pads comprises performing a planarization process to level first surfaces of the plurality of metal pads and the first dielectric layer;
forming a reconstructed wafer comprising:
a plurality of device dies; and
a second dielectric layer on the plurality of device dies; and
bonding the first composite carrier to the reconstructed wafer, wherein the plurality of metal pads physically contact the second dielectric layer,
wherein at a time of the bonding, the second dielectric layer is a blank layer free from metal features therein, and
wherein the forming the plurality of metal pads comprises:
performing a first etching process to etch the first dielectric layer and to form a first plurality of openings, until the carrier is exposed; and
filling the first plurality of openings with a metallic material, wherein the planarization process is performed on the metallic material.
